(19) United States
(12) Patent Application Publication
(10) Pub. No.: US 2007/0041414 A1
(43) Pub. Date: Feb. 22, 2007

(54) Semiconductor laser showing reduced sensitivity to disturbances

(75) Inventors: Tony Albrecht, Bad Abbach (DE); Peter Brick, Regensburg (DE); Marc Philippens, Regensburg (DE); Glenn-Yves Plaine, Regensburg (DE)

Correspondence Address: COHEN, PONTANI, LIEBERMAN & PAVANE, 551 FIFTH AVENUE, SUITE 1210, NEW YORK, NY, 10176, US

(73) Assignee: OSRAM OPTO SEMICONDUCTORS GMBH, Regensburg (DE)

(21) Appl. No.: 10/550,994

(22) PCT Filed: Feb. 23, 2004
(86) PCT No.: PCT/DE04/00333

§ 371 Date: Aug. 4, 2006

(30) Foreign Application Priority Data
Mar. 26, 2003 (DE) 103 13 609.6

(51) Int. Cl. H01S 5/00

(52) U.S. Cl. 372/50.11; 372/50.124; 372/45.013

(57) ABSTRACT

A semiconductor laser, contains at least one absorbing layer (8) in its laser resonator, said absorbing layer reducing the transmission T_{Res} of the laser radiation (10) in the laser resonator for the purpose of decreasing the sensitivity of the semiconductor laser to disturbances created by radiation (9) fed back into the laser resonator. This reduces fluctuations in the output power due to fed-back radiation (9).

The invention relates to a semiconductor laser, in particular a single-mode semiconductor laser.

This patent application claims the priority of German Patent Application 10313609.6-33, the disclosure content of which is hereby incorporated by reference.

Lasers having a good beam quality, high coherence length and low spectral width are desirable or even necessary for many applications. These properties can be obtained in particular with single-mode lasers, such as, for example, DFB lasers, trapezoidal lasers or surface emitting semiconductor lasers (VCSEL—Vertical Cavity Surface Emitting Laser).

The abovementioned lasers have a great sensitivity to fed-back light. In the context of the invention, fed-back light is understood to mean that proportion of the radiation emitted by the semiconductor laser which is scattered or reflected back into the semiconductor laser from external objects. The phase of the fed-back light depends on the optical path covered and thus on the distance between the scattering or reflecting object and the semiconductor laser. Depending on the phase, the fed-back light interferes constructively or destructively with the radiation of the semiconductor laser. Even small changes in the distance between the scattering or reflecting object and the semiconductor laser of a fraction of the emitted light wavelength can change the phase of the fed-back light in such a way that a change between constructive and destructive interference takes place. Small fluctuations of the optical system or a movement of the reflecting or scattering object thereby bring about a noise ΔP of the output power P of the semiconductor laser. This noise or the ratio of the noise to the output power ΔP/P of the semiconductor laser is a measure of the sensitivity to disturbances.

One possibility for reducing the sensitivity of a semiconductor laser to fed-back light consists in fitting absorbing or reflecting elements outside the laser resonator, said elements preventing fed-back light from penetrating into the laser resonator. However, this is technically very complicated in part.

The invention is based on the object of specifying a semiconductor laser whose sensitivity to disturbances caused by fed-back light is reduced in a technically comparatively simple manner.

This object is achieved according to the invention by means of a semiconductor laser having the features of patent claim 1. The subclaims relate to advantageous refinements of the semiconductor laser.

A semiconductor laser according to the invention contains at least one absorbing layer within the laser resonator, said absorbing layer reducing the transmission T_{Res} of the laser radiation in the laser resonator and thus decreasing the sensitivity of the semiconductor laser to disturbances created by radiation fed back into the laser resonator. In this case, the transmission T_{Res} of the laser resonator is understood to mean the factor by which radiation having the laser wavelength is attenuated during a full circulation in the resonator. The transmission T_{Res} takes account only of resonator-internal losses such as absorption or scattering, but not of the reflection losses at the mirrors, which occur particularly in the case of the coupling-out mirror. A typical value for the transmission T_{Res}, which in principle is less than 1, is approximately 0.99.

Laser operation requires a transmission T_{Res} that deviates only slightly from 1. Therefore, T_{Res} can only be decreased slightly for the purpose of decreasing the sensitivity of the semiconductor laser to disturbances. Therefore, the absorbing layer is preferably situated in the region of a node of a standing wave that forms during operation of the semiconductor laser in the laser resonator. The electric field strengths of the laser radiation are lower in this region than in the region of the antinodes of the standing wave field, so that the insertion of an absorbing medium brings about lower absorption losses there.

Preferably, in the optimization of the transmission T_{Res} of the laser resonator, the reflectivity of the laser mirrors, in particular of the coupling-out mirror, is also taken into account, and these parameters are optimized together in such a way as to produce a low sensitivity to disturbances for a wide range of possible output powers P of the semiconductor laser. These parameters may be optimized for example by means of a simulation of the noise amplitude ΔP of the semiconductor laser in a manner dependent on the variables of the transmission T_{Res} of the resonator, the reflectivity of the mirrors, and the output power of the semiconductor laser. The simulation is effected under the assumption that a part of the emitted laser radiation is fed back into the laser resonator from outside, the noise amplitude ΔP resulting from the difference in the output power in the case of a constructive and a destructive interference of the fed-back light with the laser radiation.

Optimizing the sensitivity to disturbances is expedient particularly for single-mode lasers since it is precisely on these lasers that high requirements made of the stability are imposed.

The semiconductor laser is preferably a surface emitting semiconductor laser (VCSEL). The positioning of one or more absorbing layers in the standing wave field of the resonator is simpler in the case of such a type of laser than in the case of other types of laser.

By way of example, the surface emitting semiconductor laser may contain a Bragg mirror and the absorbing layer may be arranged in said Bragg mirror. In the selection of the material and the thickness of the absorbing layer, the absorption at the emission wavelength of the laser is to be taken into account. By way of example, given an emission wavelength of approximately 850 nm it is possible to use a gallium arsenide layer that is approximately 20 nm thick.

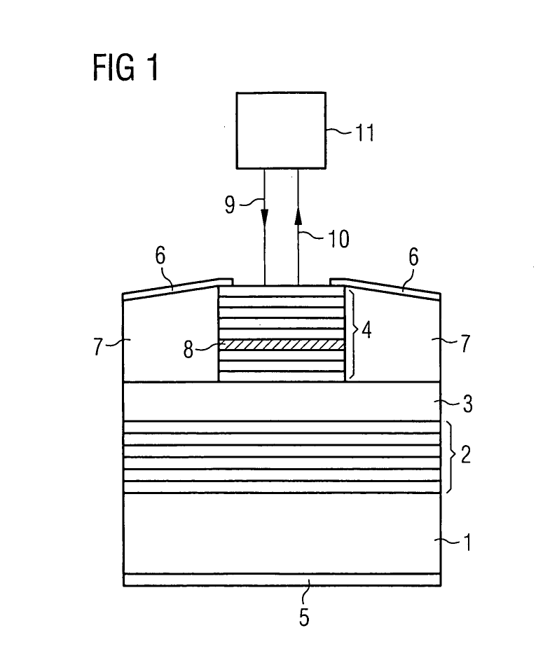

The invention is explained in more detail below on the basis of exemplary embodiments in connection with FIGS. 1, 2 and 3.

In the figures:

FIG. 1 shows a schematic illustration of a cross section through an embodiment of a surface emitting semiconductor laser which, according to the invention, contains an absorbing layer in its laser resonator,

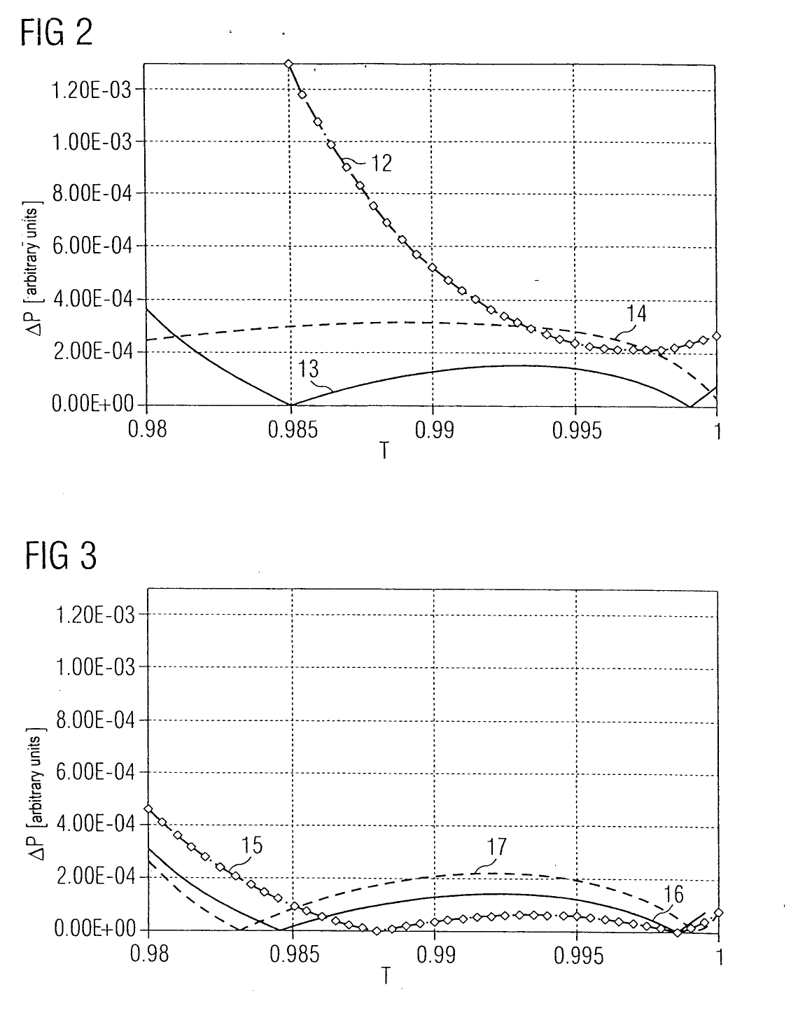

FIG. 2 shows a simulation of the noise amplitude ΔP of a semiconductor laser as a function of the transmission T_{Res} of the resonator for three different reflectivities R of the coupling-out mirror, and

FIG. 3 shows a simulation of the noise amplitude ΔP of a semiconductor laser as a function of the transmission T_{Res} of the resonator for three different output powers P of the semiconductor laser.

The surface emitting semiconductor laser illustrated schematically in cross section in FIG. 1 contains a rear-side mirror 2, an active zone 3 and a coupling-out mirror 4 as essential elements on a semiconductor substrate 1. The mirrors are preferably Bragg mirrors. Furthermore, the surface emitting semiconductor laser contains electrical contact layers 5, 6 for forming the n-type contact 5 and also the p-type contact 6.

The person skilled in the art is aware of various embodiments of such surface emitting semiconductor lasers with further, in part also patterned, intermediate layers, for example from DE 100 38 235 A1 and the documents cited therein. By way of example, this may involve passivation layers 7 or further layers for spatially delimiting the current flow.

The surface emitting semiconductor laser may also be formed as a surface emitting semiconductor laser with an external resonator (VECSEL—vertical external cavity surface emitting laser), in which the coupling-out mirror of the laser resonator is formed by an external mirror arranged outside the semiconductor body.

The laser resonator contains an absorbing layer 8, which slightly reduces the transmission T_{Res} of the laser radiation in the laser resonator and thereby reduces the sensitivity of the semiconductor laser to disturbances created by radiation 9 fed back into the laser resonator. In this case, fed-back radiation 9 is understood to mean radiation 10 which is emitted by the laser and is reflected or scattered back into the semiconductor laser from an external object 11.

The absorbing layer 8 may be contained for example in one of the Bragg mirrors 4 of the surface emitting semiconductor laser. In this case, it is necessary, if appropriate, to adapt the layers of the Bragg mirror 4 which surround the absorbing layer 8 in order to compensate for a disruption in the periodicity of the layers that is brought about by the insertion of the absorbing layer 8. Instead of one absorbing layer 8 it is also possible to provide a plurality of absorbing layers.

The transmission T_{Res} of the laser resonator is dependent in particular on the material, the thickness and the position of the absorbing layer 8 in the laser resonator and can therefore be altered by these parameters. By way of example, a gallium arsenide layer having a thickness of approximately 20 nm is suitable for an emission wavelength of 850 nm. The dependence of the absorption on the position of the absorbing layer results from the fact that the absorption effect is greater in the antinodes of the standing wave field that forms within the laser resonator than in the nodes of the standing wave field. Since, with the absorbing layer 8, although the transmission T_{Res} of the resonator is intended to be reduced, at the same time the laser operation is not intended to be disrupted, the absorbing layer is preferably positioned in a node of the standing wave field.

The optimum value for the transmission T_{Res} of the laser resonator in order to achieve a minimization of the sensitivity of the semiconductor laser to disturbances created by fed-back light also depends on the reflectivity of the coupling-out mirror 4 and the output power of the semiconductor laser. FIG. 2 shows a simulation of the noise amplitude of the output power ΔP, which serves as a measure of the sensitivity to disturbances, as a function of the transmission T_{Res} of the laser resonator for three different reflectivities R of the coupling-out mirror 4. The curve 12 shows the sensitivity to disturbances for a reflectivity of the coupling-out mirror of R=99.3%, the curve 13 for a reflectivity of the coupling-out mirror of R=99.6%, and the curve 14 for a reflectivity of the coupling-out mirror of R=99.8%. The simulation illustrates that a minimum sensitivity to disturbances can be obtained only with specific combinations of the transmission T_{Res} of the laser resonator and the reflectivity of the coupling-out mirror 4. By way of example, an advantageous value for the transmission T_{Res} of the laser resonator which can be set by means of the parameters of the absorbing layer 8 is approximately 0.985 in accordance with the simulation for a reflectivity of the coupling-out mirror of R=99.6%.

The diagram of FIG. 3 shows the noise amplitude ΔP of the semiconductor laser as a function of the transmission T_{Res} of the laser resonator for a fixed value of the reflectivity of the coupling-out mirror 4 of R=99.6% for three different output powers of the semiconductor laser. The curve 15 shows the dependence for an output power of P=0.7 mW, the curve 16 for P=1 mW and the curve 17 for P=1.3 mW. For a semiconductor laser provided for use at different output powers, the transmission T_{Res} of the laser resonator is preferably set such that the noise amplitude ΔP is low for a wide range of output powers. In the example simulated in FIG. 3, it is expedient to set the transmission T_{Res} of the laser resonator to a value of 0.986 by insertion of a suitable absorbing layer 8 since the noise amplitude ΔP for T_{Res}=0.986 is low for all the output powers considered.

The scope of protection of the invention is not restricted by the description of the invention on the basis of the exemplary embodiments. Rather, the invention encompasses any new feature and also any combination of features, which in particular comprises any combination of features in the patent claims, even if this combination is not explicitly specified in the patent claims.

1. A semiconductor laser, comprising:
at least one absorbing layer (8) within the laser resonator, said absorbing layer reducing the transmission T_{Res} of the laser radiation (10) in the laser resonator for the purpose of decreasing the sensitivity of the semiconductor laser to disturbances created by the radiation (9) fed back into the laser resonator.

2. The semiconductor laser as claimed in claim 1,
in which the absorbing layer (8) is situated in a node of a standing wave that forms during operation of the semiconductor laser in the laser resonator.

3. The semiconductor laser as claimed in claim 1, in which the reflectivity of the mirrors of the resonator and the transmission T_{Res} of the laser radiation during a resonator circulation are set so as to produce a low sensitivity to disturbances for a wide range of possible output powers of the semiconductor laser.

4. The semiconductor laser as claimed in claim 1, in which the semiconductor laser is a single-mode laser.

5. The semiconductor laser as claimed in claim 1, in which the semiconductor laser is a surface emitting semiconductor laser (VCSEL).

6. The semiconductor laser as claimed in claim 1, in which the semiconductor laser is a surface emitting semiconductor laser with an external resonator (VECSEL).

7. The semiconductor laser as claimed in claim 6, in which the surface emitting semiconductor laser contains a Bragg mirror (4) and the absorbing layer (8) is contained in said Bragg mirror (4).

8. The semiconductor laser as claimed in claim 1,
in which the absorbing layer (8) is a gallium arsenide layer.

9. The semiconductor laser as claimed in claim 1 one of claims 1 to 8, in which the gallium arsenide layer is approximately 20 nm thick.

10. The semiconductor laser as claimed in claim 1, which contains a plurality of absorbing layers within the laser resonator.

11. The semiconductor laser as claimed in claim 5, in which the surface emitting semiconductor laser contains a Bragg mirror (4) and the absorbing layer (8) is contained in said Bragg mirror (4).
